(19) United States
(12) Patent Application Publication
(10) Pub. No.: US 2026/0173595 A1
(43) Pub. Date: Jun. 18, 2026

(54) SEMICONDUCTOR DEVICE AND MANUFACTURING METHOD THEREOF

(71) Applicant: EPISTAR CORPORATION, Hsinchu (TW)

(72) Inventors: Jih-Kang CHEN, Hsinchu (TW); Cai-Jhen SONG, Hsinchu (TW); Chia-Hao CHANG, Hsinchu (TW); Chen OU, Hsinchu (TW); Wei-Chun LIAO, Hsinchu (TW); Ching-Han LIAO, Hsinchu (TW); Ching-Hua SU, Hsinchu (TW)

(21) Appl. No.: 19/410,806

(22) Filed: Dec. 5, 2025

(30) Foreign Application Priority Data
Dec. 12, 2024 (TW) 113148380

(51) Int. Cl. H10H 20/84; H10H 20/01; H10H 20/82; H10H 20/841; H10H 20/857

(52) U.S. Cl. CPC H10H 20/84; H10H 20/032; H10H 20/034; H10H 20/82; H10H 20/841; H10H 20/857

(57) ABSTRACT

A semiconductor device, includes: a semiconductor stack, including a top surface, a bottom surface and a side wall; and an insulating structure, covering the semiconductor stack; wherein: the side wall includes a first sub-side wall connected to the bottom surface; and the insulating structure covers the first sub-side wall and a portion of the insulating structure covering the first sub-side wall comprises a gradient thickness that gradually decreases toward the bottom surface.

### CROSS-REFERENCE TO RELATED APPLICATIONS

This application claims priority to and the benefit of Taiwan patent application No. 113148380 filed on Dec. 12, 2024, and the content of which is incorporated by reference in its entirety.

### BACKGROUND

### Technical Field

The present application relates to a semiconductor device, and more particularly to a semiconductor device including an insulating structure.

### Description of the Related Art

Semiconductor devices include compound semiconductors composed of group III-V elements, such as gallium phosphide (GaP), gallium arsenide (GaAs), gallium nitride (GaN), and aluminum nitride (AlN). A semiconductor device may be an optoelectronic device, such as a light-emitting diode (LED), laser, photodetector, or solar cell. It may also be a power device or an acoustic wave device. Taking the LED as an example, the LED is a solid-state semiconductor which has advantages such as low power consumption, low heat generation, long operating life, vibration resistance, small size, fast response, and favorable optoelectronic characteristics, e.g., a stable emission wavelength. Accordingly, LEDs are widely used in home appliances, indicator lamps, and optoelectronic products. However, as the size of LEDs continues to shrink, maintaining their optoelectronic characteristics while improving manufacturing yield has become one of the objectives pursued by those of ordinary skill in the art.

### SUMMARY OF THE DISCLOSURE

A semiconductor device, includes: a semiconductor stack, including a top surface, a bottom surface and a side wall; and an insulating structure, covering the semiconductor stack; wherein: the side wall includes a first sub-side wall connected to the bottom surface; and the insulating structure covers the first sub-side wall and a portion of the insulating structure covering the first sub-side wall comprises a gradient thickness that gradually decreases toward the bottom surface.

### BRIEF DESCRIPTION OF THE DRAWINGS

FIG. 1 is a cross-sectional view of a light-emitting device 1 in accordance with an embodiment of the present application.

FIGS. 2A-2I show a manufacturing method of the light-emitting device 1 in accordance with an embodiment of the present application.

FIG. 3 shows a cross-sectional view of a light-emitting device 2 in accordance with another embodiment of the present application.

FIG. 4 shows a scanning electron microscope (SEM) image of the light-emitting device 2.

FIG. 5 shows a cross-sectional view of a light-emitting device 3 in accordance with another embodiment of the present application.

FIG. 6 shows a schematic cross-sectional view of a light-emitting module 100 in accordance with an embodiment of the present application.

FIG. 7 shows a schematic plan view of a display module 105 in accordance with an embodiment of the present application.

### DETAILED DESCRIPTION

The following disclosure provides numerous embodiments to implement different features of the present disclosure. Specific examples describing various components and their arrangements are set forth to simplify the description. These specific examples are provided for illustrative purposes and are not intended to limit the present disclosure. For example, when an embodiment of the disclosure states that a first component is formed on or above a second component, it encompasses embodiments in which the first and second components are in direct contact, as well as embodiments in which additional components are disposed therebetween such that the first and second components may not be in direct contact.

It should be understood that additional process steps may be performed before, between, or after the recited method steps, and in other embodiments of the method, certain steps may be substituted or omitted. In addition, directional terminology (e.g., “beneath,” “below,” “lower,” “above,” “upper,” “higher,” and similar terms) is used for ease of description to indicate the relationships between one or more elements or feature components and other elements or feature components in the drawings. Such directional terminology encompasses the orientation of a device during use or operation as well as the orientations depicted in the figures. When the device is reoriented (e.g., rotated by 45 degrees or otherwise), the directional terminology used herein is to be interpreted accordingly. Moreover, references to a first layer being on, or above, a second layer include cases in which the first and second layers are in direct contact, as well as cases in which one or more intervening layers are present such that the first and second layers may not be in direct contact. In certain embodiments of the disclosure, terms pertaining to coupling or connection, such as “connected” and “interconnected,” unless specifically defined otherwise, may refer to structures in direct contact or structures not in direct contact with one or more intervening structures disposed therebetween, and may also encompass situations in which both structures are movable or both are fixed.

It should be understood that although terms such as “first,” “second,” “third,” etc., are used herein to describe different elements, components, regions, layers, and/or sections, such elements, components, regions, layers, and/or sections should not be limited by these terms. These terms are used only to distinguish one element, component, region, layer, or section from another. Accordingly, without departing from the technical scope of the disclosure, an element, component, region, layer, or section discussed as “first” may alternatively be referred to as “second,” and vice versa.

In some embodiments, the semiconductor device may be an optoelectronic device such as an LED, a laser, a photodetector, a solar cell, or a power device. Using a light-emitting device as an example, the main structure of the semiconductor device includes a buffer structure and a device structure formed on the buffer structure. Depending on the function of the device, different device structures may be formed. For instance, the device structure of a light-emitting device includes a semiconductor light-emitting stack comprising a p-type semiconductor layer, an n-type semiconductor layer, and an active region. The active region includes a light-emitting region and may emit light of different wavelengths depending on the materials. Multiple embodiments are provided below to describe aspects of the semiconductor device. It is understood that the semiconductor devices in these embodiments are for illustrative purposes and are not intended to limit the scope of the present application.

In the present application, unless otherwise specified, the formula AlGaN represents AlₐGa₍₁₋ₐ₎N, where 0≤a≤1; the formula InGaN represents In_{b}Ga_{(1-b)}N, where 0≤b≤1; the formula AlInGaN represents Al_{c}In_{d}Ga_{(1-c-d)}N, where 0≤c≤1, 0≤d≤1. The formula AlInGaP represents (AlₑIn₍₁₋ₑ₎)_{1-f}Ga_{f}P, where 0≤e≤1, 0≤f≤1; the formula InGaAsP represents In_{g}Ga_{1-g}AsₕP₁₋ₕ, where 0≤g≤1, 0≤h≤1. Adjusting the content of the elements can achieve different purposes, including but not limited to adjusting energy levels or tuning the main emission wavelength of the light-emitting device.

The composition and dopants of each layer included in the semiconductor device illustrated in the present application can be analyzed by any suitable method, such as secondary ion mass spectrometry (SIMS).

The width or thickness of each layer or structure included in the semiconductor device illustrated in the present application can be analyzed by any suitable method, such as transmission electron microscopy (TEM) or scanning electron microscopy (SEM).

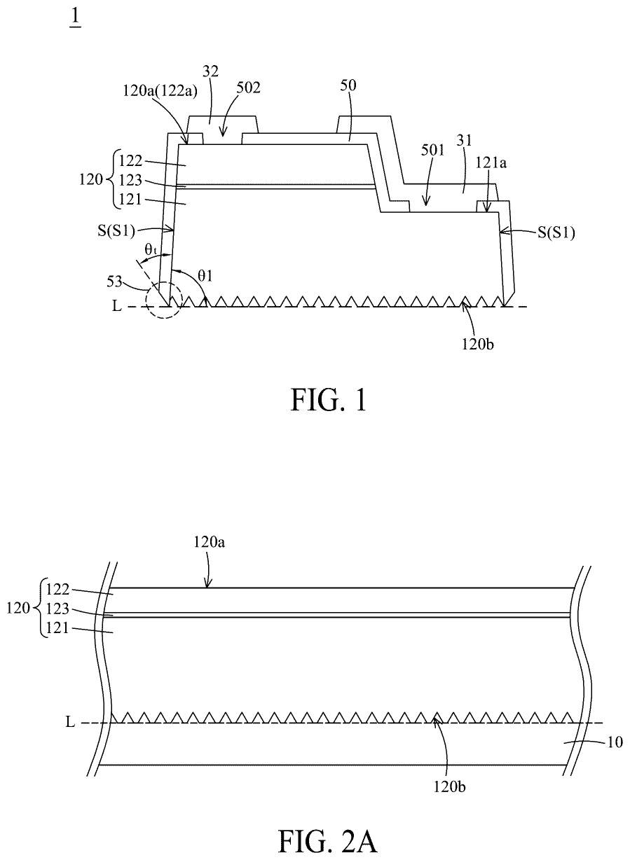

The following embodiments use a light-emitting device as an example of the semiconductor device. FIG. 1 shows a cross-sectional view of a light-emitting device 1 in accordance with an embodiment of the present application. As shown in FIG. 1, the light-emitting device 1 includes a semiconductor stack 120 and an insulating structure 50 covering the semiconductor stack 120. The semiconductor stack 120 includes a first semiconductor layer 121, an active region 123, and a second semiconductor layer 122. The second semiconductor layer 122 is disposed on the first semiconductor layer 121, and the active region 123 is disposed between the first semiconductor layer 121 and the second semiconductor layer 122. The semiconductor stack 120 includes a top surface 120a, a bottom surface 120b, and a side wall S connecting the top surface 120a and the bottom surface 120b. The bottom surface 120b is opposite to the top surface 120a and substantially parallel with the top surface 120a. The insulating structure 50 covers the top surface 120a and the side wall S of the semiconductor stack 120. In one embodiment, the insulating structure 50 may cover a portion of the top surface 120a of the semiconductor stack 120, and may cover a portion or all of the side wall S.

In one embodiment, the light-emitting device 1 may further include a first electrode 31 and a second electrode 32. The first and second electrodes 31, 32 may be disposed on the same side or on opposite sides of the semiconductor stack 120 according to different designs. In an embodiment in which the first and second electrodes 31, 32 are on the same side of the semiconductor stack 120, the insulating structure 50 may include a first opening 501 and a second opening 502 respectively located on the first semiconductor layer 121 and the second semiconductor layer 122. The first electrode 31 is disposed in the first opening 501 of the insulating structure 50 and contacts or is electrically connected to the first semiconductor layer 121. The second electrode 32 is disposed in the second opening 502 of the insulating structure 50 and contacts or is electrically connected to the second semiconductor layer 122. In another embodiment, when the first and second electrodes 31, 32 are on different sides of the semiconductor stack 120, the insulating structure 50 may include only the second opening 502 on the second semiconductor layer 122. The second electrode 32 fills the second opening 502 of the insulating structure 50 and contacts or is electrically connected to the second semiconductor layer 122. The first electrode 31 is disposed on a side of the semiconductor stack opposite the second semiconductor layer 122 and is in contact with or electrically connected to the first semiconductor layer 121, thereby forming a vertical light-emitting device. The following description refers to the embodiment in which the first and second electrodes 31, 32 are on the same side of the semiconductor stack 120.

As shown in FIG. 1, the insulating structure 50 of the light-emitting device 1 is conformally disposed on the semiconductor stack 120 to cover the top surface 120a and the side wall S. The side wall S includes a first sub-side wall S1, which is connected to the top surface 120a and the bottom surface 120b. A first included angle θ1 is formed between the first sub-side wall S1 and the bottom surface 120b. In one embodiment, the bottom surface 120b of the semiconductor stack 120 includes a patterned structure. The bottom surface 120b has a virtual horizontal reference line L, and the first included angle θ1 of the first sub-side wall S1 relative to the bottom surface 120b is defined with respect to the virtual horizontal reference line L. The insulating structure 50 covers the first sub-side wall S1. In one embodiment, the insulating structure 50 covering the first sub-side wall S1 has a gradient thickness. In one embodiment, as shown in FIG. 1, the thickness on the first sub-side wall S1 gradually decreases toward the bottom surface 120b. In a plan view (not shown), the light-emitting device 1 has a diagonal length between 1-200 μm.

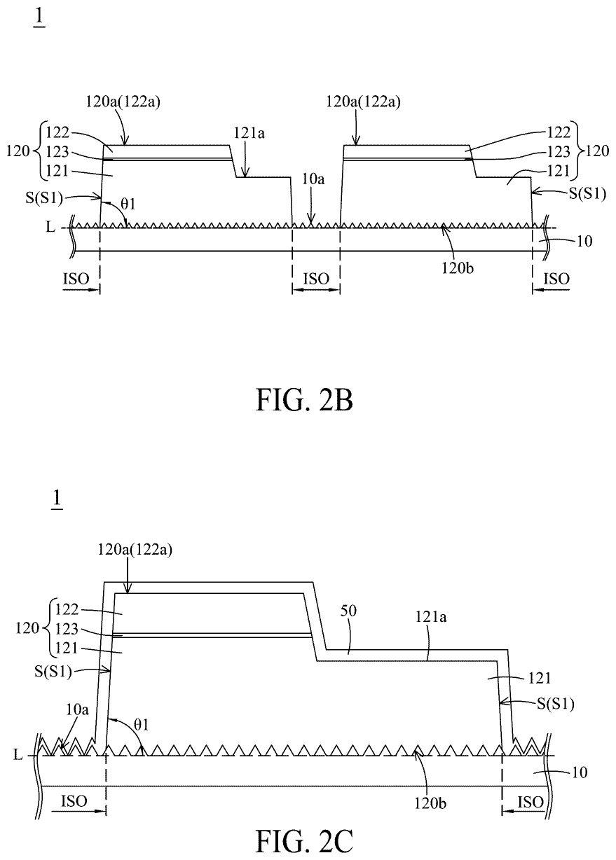

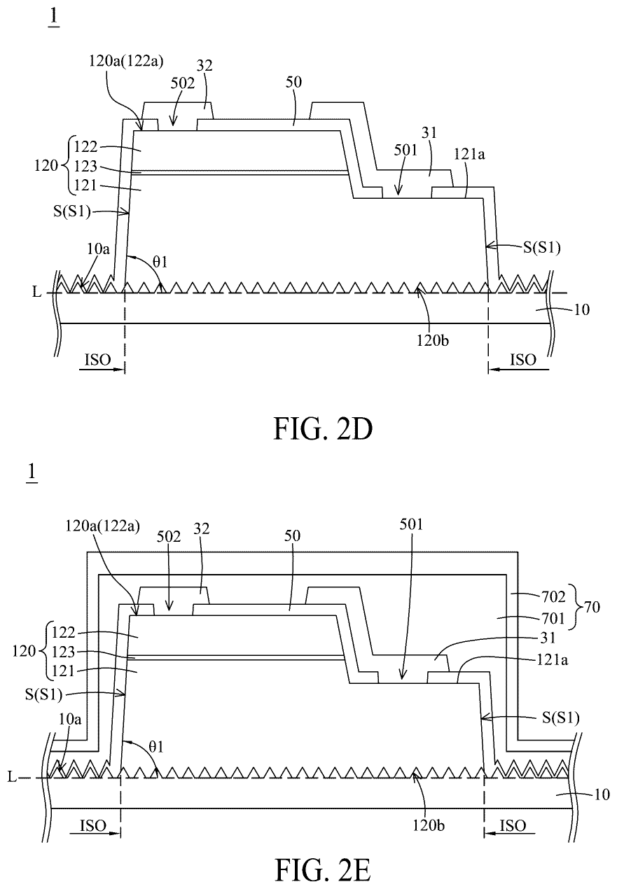

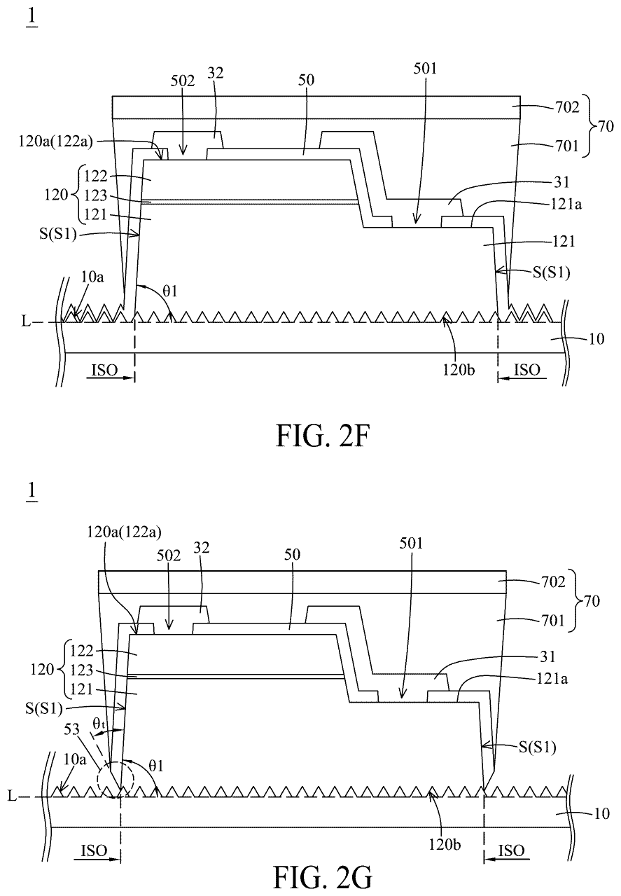

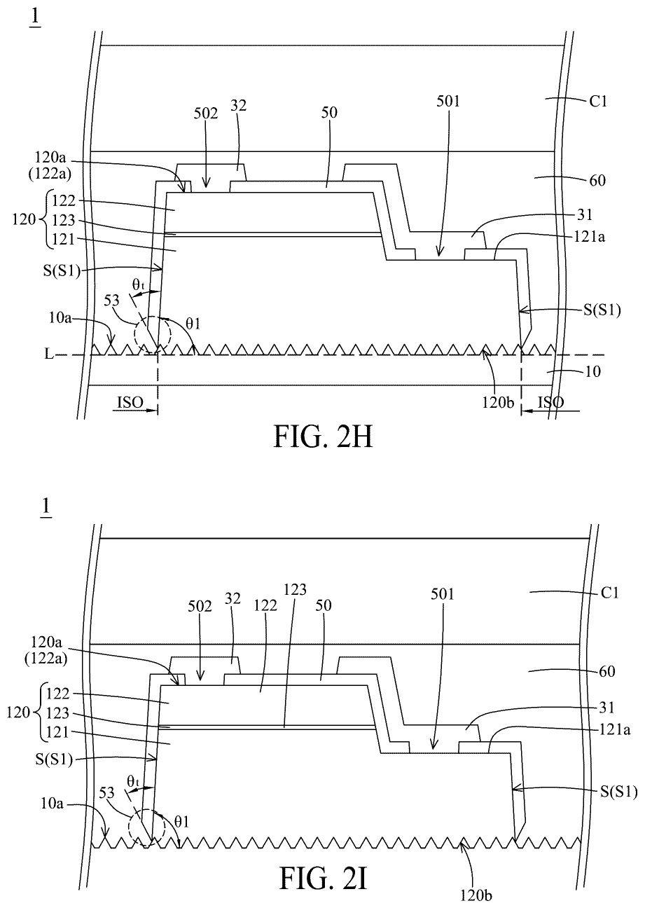

FIGS. 2A-2I show a method for forming the light-emitting device 1 in accordance with an embodiment of the present application. Referring to FIG. 2A, in one embodiment, the method for forming the light-emitting device 1 includes providing a substrate 10, and then forming a semiconductor stack 120 on the substrate 10. In the present application, the substrate 10 may be a wafer-level substrate or a chip-level substrate. In an embodiment in which the substrate 10 is a wafer-level substrate, a plurality of light-emitting devices 1 are formed on the substrate 10. The substrate 10 may be a growth substrate for epitaxially growing the semiconductor stack 120. Examples of growth substrates include GaAs substrate for epitaxially growing AlGaInP, or a sapphire substrate, GaN substrate, SiC substrate, or AlN substrate for growing GaN, InGaN, or AlGaN. In another embodiment, the substrate 10 may be a supporting substrate, and the semiconductor stack 120 includes, from bottom to top, a first semiconductor layer 121, an active region 123, and a second semiconductor layer 122. After the semiconductor stack 120 is epitaxially grown on a growth substrate, the semiconductor stack 120 may be transferred to the supporting substrate by wafer transfer. The growth substrate may then be selectively removed as needed, thereby forming a wafer or chip including the supporting substrate. The supporting substrate may include conductive materials (e.g., silicon (Si), aluminum (Al), copper (Cu), tungsten (W), molybdenum (Mo), gold (Au), silver (Ag), SiC, or alloys thereof), thermally conductive materials (e.g., diamond, graphite, ceramics, or aluminum nitride), or transparent materials (e.g., glass or sapphire).

In one embodiment of the present application, the semiconductor stack 120 may be formed by metal-organic chemical vapor deposition (MOCVD), molecular beam epitaxy (MBE), hydride vapor phase epitaxy (HVPE), physical vapor deposition (PVD), or electroplating. PVD includes sputtering or evaporation.

In one embodiment in which the semiconductor stack 120 includes a light-emitting stack, the emission wavelength of the light-emitting device 1 may be adjusted by changing the physical and chemical composition of one or more layers in the semiconductor stack 120. In one embodiment, the emission wavelength of the active region 123 may be adjusted by changing the material of the active region 123 or the compositional ratios of its constituent elements. The semiconductor stack 120 may include group III-V semiconductor materials, such as AlₓIn_{y}Ga_{(1-x-y)}N or AlₓIn_{y}Ga_{(1-x-y)}P, where 0≤x,y≤1 and (x+y)≤1. When the semiconductor stack 120 includes AlInGaP, the semiconductor stack 120 may emit red light with a wavelength between 610 nm and 650 nm. When the semiconductor stack 120 includes InGaN, the semiconductor stack 120 may emit blue light with a wavelength between 400 nm and 490 nm, or green light with a wavelength between 500 nm and 570 nm. When the semiconductor stack 120 includes AlGaN or AlInGaN, the semiconductor stack 120 may emit ultraviolet light with a wavelength between 250 nm and 400 nm.

The first semiconductor layer 121 and the second semiconductor layer 122 may be cladding layers or confinement layers and may have different conductivity types, electrical properties, or polarities, or may be doped to provide electrons or holes. For example, the first semiconductor layer 121 may be an n-type semiconductor, and the second semiconductor layer 122 may be a p-type semiconductor. The active region 123 is formed between the first semiconductor layer 121 and the second semiconductor layer 122, wherein electrons and holes recombine upon current injection, thereby converting electrical energy into optical energy and emitting light. The active region 123 may be a single heterostructure (SH), a double heterostructure (DH), a double-side double heterostructure (DDH), or a multi-quantum well (MQW) structure. The active region 123 may include a semiconductor material that is undoped, p-type, or n-type. Each of the first semiconductor layer 121, the active region 123, and the second semiconductor layer 122 may be a single layer or a structure including multiple sublayers.

In one embodiment, the semiconductor stack 120 may include a buffer structure (not shown) between the first semiconductor layer 121 and the substrate 10. The buffer structure can reduce lattice mismatch and suppress dislocations, thereby improving epitaxial quality. The buffer structure may be formed by GaN, AlGaN, or AlN. In one embodiment, the buffer structure includes multiple sublayers (not shown) having the same or different materials. In one embodiment, the buffer structure includes two sublayers formed by different processes, for example, the first sublayer is formed by sputtering and the second sublayer by MOCVD. In another embodiment, the buffer structure further includes a third sublayer formed by MOCVD, and the growth temperature of the second sublayer differs from that of the third sublayer. In one embodiment, the first, second, and third sublayers are of the same material, for example, AlN.

Next, referring to FIG. 2B, the semiconductor stack 120 is patterned. For ease of description, the semiconductor stack after patterning is hereinafter referred to as the semiconductor stack 120. In one embodiment, the semiconductor stack 120 is patterned by an etching process to remove portions of the second semiconductor layer 122 and the active region 123, thereby exposing the top surface 121a of the first semiconductor layer 121. In another embodiment, patterning the semiconductor stack 120 includes removing portions of the second semiconductor layer 122, the active region 123, and the first semiconductor layer 121 to expose a portion of the top surface 10a of the substrate 10, thereby forming a separation region ISO. The separation region ISO defines the outline of a plurality of semiconductor stacks 120 of the light-emitting devices 1 and defines the periphery of each light-emitting device 1. Any two adjacent light-emitting devices 1 are separated by the separation region ISO. For ease of explanation regarding the structures and process steps of the plurality of light-emitting devices 1, a single light-emitting device 1 will be described as representative hereinafter. After the patterning step, the first semiconductor layer 121 of the light-emitting device 1 has the side wall S, which includes the first sub-side wall S1. In one embodiment, the first included angle θ1 between the first sub-side wall S1 and the bottom surface 120b is a right angle or an acute angle, and the magnitude of θ1 can be adjusted by the etching process. In one embodiment, θ1 is between 50° and 90°, or between 60° and 90°.

Next, referring to FIG. 2C, the insulating structure 50 is formed on the semiconductor stack 120 and the substrate 10. The insulating structure 50 is conformally disposed on the semiconductor stack 120 to cover the top surface 120a and the side wall S, is in contact with the top surface 121a of the first semiconductor layer 121, and extends to cover the top surface 10a of the substrate 10 in the separation region ISO.

In one embodiment, the insulating structure 50 may be a single-layer structure formed of insulating materials such as silicon oxide, silicon nitride, or silicon oxynitride. In another embodiment, the insulating structure 50 includes a plurality of first sublayers and a plurality of second sublayers alternately stacked (not shown). The plurality of first sublayers have a first refractive index, and the plurality of second sublayers have a second refractive index different from the first. By alternately stacking two or more materials having different refractive indices, a distributed Bragg reflector (DBR) structure is formed to selectively reflect light within a specific wavelength range or a specific angle ranges, thereby improving the brightness of the light-emitting device 1. The insulating structure 50 includes non-conductive material which can be organic or inorganic. The organic materials include SU-8, benzocyclobutene (BCB), perfluorocyclobutane (PFCB), epoxy, acrylic resin, cyclic olefin copolymer (COC), polymethyl methacrylate (PMMA), polyethylene terephthalate (PET), polycarbonate (PC), polyetherimide, or fluorocarbon polymers. The inorganic materials include silicone, glass, aluminum oxide (Al₂O₃), silicon nitride (SiNₓ), silicon oxide (SiOₓ), titanium oxide (TiOₓ), or magnesium fluoride (MgFₓ). The first refractive index material can be a high-refractive index material such as TiO₂, Si₃N₄, Nb₂O₅, or Ta₂O₅, and the second refractive index material can be a low-refractive index material such as SiO₂, MgF₂, or CaF₂. The single layer or the multiple sublayers of the insulating structure 50 may be disposed on the semiconductor stack 120 by PVD, CVD, atomic layer deposition (ALD) or spin-coating.

In other embodiments, the insulating structure 50 may further include additional layers beyond the first and second sublayers. For example, the insulating structure 50 may further include a base layer (not shown) disposed between the first and second sublayers and the semiconductor stack 120. That is, the base layer is first formed on the semiconductor stack 120, followed by formation of the first and second sublayers on the base layer. The base layer may protect the light-emitting device or the semiconductor stack. For example, the base layer prevents moisture from penetrating the light-emitting device. The base layer includes insulating material, which may be the same as one of, or different from both of, the first and second sublayers. The base layer has a thickness greater than those of the first and second sublayers. In one embodiment, the base layer is formed by a process different from that for the first and second sublayers, e.g., by chemical vapor deposition (CVD), and preferably by plasma-enhanced CVD (PECVD), whereas the first and second sublayers are formed by sputtering or evaporation. In another embodiment, the base layer is formed by the same process as that used for the first and second sublayers. For example, the base layer, first sublayer, and second sublayer are formed by PVD such as evaporation, sputtering, or a combination thereof, thereby yielding a smoother surface of the insulating structure 50. In another embodiment, the insulating structure 50 further includes a top layer (not shown) disposed over the first and second sublayers on the side opposite the second semiconductor layer 122. That is, the first and second sublayers are formed on the semiconductor stack 120, followed by the top layer. In one embodiment, the top layer increases the mechanical strength of the insulating structure 50 so that the insulating structure 50 is less likely to crack when subjected to external force. The top layer includes insulating material, which may be the same as one of, or different from both of, the first and second sublayers. The top layer has a thickness greater than those of the first and second sublayers. Similar to the base layer, the top layer may be formed by a process different from or the same as that of the first and second sublayers. In another embodiment, the insulating structure 50 includes a stack composed of the first and second sublayers, and further includes the base layer and/or the top layer. In another embodiment, the insulating structure 50 includes a dense layer (not shown) formed on the semiconductor stack 120 by ALD to protect the semiconductor stack 120. The dense layer may be located at the bottommost or topmost portion of the insulating structure 50, or between any two of the aforementioned stack, base layer, and top layer. The dense layer may have a thickness between 50 Å and 2000 Å, or between 100 Å and 1500 Å. The dense layer may be formed of silicon oxide, aluminum oxide, hafnium oxide, zirconium oxide, yttrium oxide, lanthanum oxide, tantalum oxide, silicon nitride, aluminum nitride, or silicon oxynitride. In one embodiment, the dense layer conformally covers the underlying structures (e.g., the semiconductor stack 120). Due to its good step coverage characteristics, it can protect the underlying structure, such as preventing moisture from entering the semiconductor stack 120. In another embodiment, the dense layer disposed at the topmost portion of the insulating structure 50 may enhance adhesion between the insulating structure 50 and overlying structures (such as electrodes 31 and 32).

Next, referring to FIG. 2D, a first opening 501 and a second opening 502 are formed in the insulating structure 50. The first opening 501 is disposed on the top surface 121a of the first semiconductor layer 121, and the second opening 502 is disposed on the top surface 122a of the second semiconductor layer 122. In a plan view of the light-emitting device 1, each of the first opening 501 and the second opening 502 in the insulating structure 50 may be circular, semicircular, elliptical, triangular, rectangular, polygonal, arcuate, or annular. Then, the first electrode 31 and the second electrode 32 are formed. The first electrode 31 is disposed on the insulating structure 50, fills the first opening 501, and is electrically connected to the first semiconductor layer 121. The second electrode 32 is disposed on the insulating structure 50, fills the second opening 502, and is electrically connected to the second semiconductor layer 122. The first and second electrodes 31, 32 provide current paths for supplying power from an external power source to the first and second semiconductor layers 121, 122, respectively. The electrodes 31, 32 may include metal materials such as Cr, Ti, W, Au, Al, In, Sn, Ni, Rh, Cu, Pt, or an alloy thereof. The electrodes 31, 32 may be formed of a single layer or multiple layers. For example, the electrodes 31, 32 may include Ti/Au, Ti/Pt/Au, Cr/Au, Cr/Pt/Au, Ni/Au, Ni/Pt/Au, or Cr/Al/Cr/Ni/Au.

In one embodiment, the light-emitting device 1 may further include a contact electrode (not shown) between the insulating structure 50 and the semiconductor stack 120. The first opening 501 and/or the second opening 502 of the insulating structure 50 exposes the contact electrode. Specifically, before forming the insulating structure 50, one or more contact electrodes may be formed on the top surface 121a of the first semiconductor layer 121 and/or on the second semiconductor layer 122. In other words, the contact electrode is exposed by the first opening 501 or the second opening 502 of the insulating structure 50. The contact electrode may include a transparent electrode. Materials for the transparent electrode include graphene, transparent conductive oxide (TCO), or a thin metal. The TCO includes indium tin oxide (ITO), indium oxide (In2O3), zinc oxide (ZnO), zinc indium tin oxide (ZITO), zinc indium oxide (ZIO), zinc tin oxide (ZTO), gallium indium tin oxide (GITO), gallium indium oxide (GIO), or gallium zinc oxide (GZO). The TCO may include various dopants, such as aluminum-doped zinc oxide (AZO) or fluorine-doped tin oxide (FTO). The thin metal includes, for example, Ni or Au.

In one embodiment, the light-emitting device 1 further includes one or more etch stop layers (not shown) disposed between the insulating structure 50 and the semiconductor stack 120, and optionally disposed on the contact electrode, to prevent subsequent etching processes from damaging the underlying first semiconductor layer 121, second semiconductor layer 122, and/or the contact electrode(s). The etch stop layer may include, for example, metal. In one embodiment (not shown), the first opening 501 and/or the second opening 502 of the insulating structure 50 exposes the etch stop layer.

Next, the insulating structure 50 is patterned. Referring to FIGS. 2E-2F, in one embodiment, the insulating structure 50 is patterned by photolithography. The patterning process includes removing the insulating structure 50 on the separation region ISO and patterning the portion of the insulating structure 50 covering the first sub-side wall S1. In one embodiment, patterning the insulating structure 50 includes forming a photoresist structure 70 on the insulating structure 50.

In another embodiment, the photoresist structure 70 includes multiple resist layers, for example, a first photoresist layer 701 and a second photoresist layer 702. As shown in FIG. 2E, the first photoresist layer 701 is formed on the insulating structure 50, and the second photoresist layer 702 is formed on the first photoresist layer 701. Referring to FIG. 2F, photolithography is then performed. Using positive resists as an example, a photomask (not shown) shields the semiconductor stack 120 but does not fully shield the separation region ISO. The unshielded portions of the first photoresist layer 701 and the second photoresist layer 702 are removed after exposure and development. By setting the mask shielding area and alignment, the remaining first photoresist layer 701 can cover the insulating structure 50 over the side wall S, whereas the second photoresist layer 702 does not cover the side wall S after photolithography. In one embodiment, the development rate of the material of the first photoresist layer 701 is greater than that of the second photoresist layer 702. After exposure and development, the remaining first photoresist layer 701 is recessed relative to the nominal masked area, thereby forming an undercut, e.g., an upper-wide, lower-narrow profile in cross-section. The development rate of the first photoresist material is greater than that of the second photoresist material. The materials for the first and second photoresist layers 701, 702 are not particularly limited. In one embodiment, the first photoresist layer 701 may be a lift-off resist (LOR). In other embodiments, the photoresist structure 70 may include a single resist layer. The single resist layer can be configured through mask and process conditions to form a similar undercut.

Then, a portion of the insulating structure 50 is removed. As shown in FIG. 2G, the insulating structure 50 on the substrate 10 is etched so that a part of the insulating structure 50 on the separation region ISO can be removed. Meanwhile, due to the undercut of the first photoresist layer 701, the part of the insulating structure 50 located on the first sub-side wall S1 beneath the bottom of the undercut forms a gradient thickness that gradually decreases toward the bottom surface 120b, thereby forming a tapered end portion 53 of the insulating structure 50. In a cross-sectional view, the tapered end portion 53 defines an included angle θt with respect to first sub-side wall S1. This reduces the contact area between the end portion 53 of the insulating structure 50 near the bottom surface 120b and the substrate 10, facilitating subsequent separation of the insulating structure from the substrate. In one embodiment, the end portion 53 of the insulating structure 50 is not connected to the top surface 10a of the substrate 10. In another embodiment (not shown), the insulating structure 50 on the separation region ISO is not completely removed; instead, a slight remaining thickness of the insulating structure 50 is left on the top surface 10a of the substrate 10, and the tapered end portion 53 is connected to this slight remaining thickness on the top surface 10a. The slight thickness may be, for example, less than 10% of the thickness of the insulating structure 50 over the semiconductor stack 120. In some embodiments, inductively coupled plasma (ICP), reactive-ion etching (RIE), or atomic layer etching (ALE) may be used to etch the insulating structure 50 on the substrate. In the present embodiment, ICP etching is used. Finally, the first and second photoresist layers 701, 702 are removed.

In the present application, the order of steps in the method for manufacturing the light-emitting device 1 may be modified without departing from the technical principles and spirit of the invention. For example, in another embodiment (not shown), after FIG. 2C, the insulating structure 50 is patterned first, that is, the end portion 53 of the insulating structure 50 is formed as described above, followed by formation of the first opening 501, the second opening 502, the first electrode 31, and the second electrode 32.

The morphology of the gradient thickness of the insulating structure 50 is not particularly limited. In one embodiment, the insulating structure 50 covering the first sub-side wall S1 extends from the top surface 120a toward the bottom surface 120b with a thickness gradient. In one embodiment, the thickness gradually decreases toward the bottom surface 120b, and a part of the first sub-side wall S1 may be exposed near the bottom surface 120b. In the present embodiment shown in FIG. 2G, the insulating structure 50 has an outer surface opposite the first sub-side wall S1, which is substantially parallel to the first sub-side wall S1, and the included angle θt is formed at the end portion 53. In another embodiment, the gradient thickness of the insulating structure 50 has a fixed slope, and the angle of the slope corresponds to the included angle θt. In another embodiment (not shown), the end portion 53 of the insulating structure 50 may include an arcuate surface.

In one embodiment, the included angle θt of the end portion 53 is between 0.5° and 90°, or between 20° and 80°.

In one embodiment of the present application, the method further includes separating the semiconductor stack 120 from the substrate 10. Referring to FIG. 2H, the semiconductor stack 120 is bonded to a supporting substrate C1 by an adhesive structure 60. The bonding process may employ heat, pressure, or a combination thereof. The insulating structure 50 and the first and second electrodes 31, 32 are in direct contact with the adhesive structure 60. Referring to FIG. 2I, the substrate 10 is then separated from the semiconductor stack 120 by laser lift-off or chemical lift-off. The adhesive structure 60 may include a polymer, such as polyimide (PI), epoxy, polybenzoxazole (PBO), polysiloxane, acrylic resin, cyclic olefin polymer (COC or COP), or benzocyclobutene (BCB). After removing the substrate 10, the adhesive structure 60 may be further removed.

In a comparative example in which the insulating structure 50 is formed as a continuous film on both the side wall S of the semiconductor stack 120 and the substrate 10, that is, a continuous film of the insulating structure 50 is present at the junction between the side wall S and the substrate 10, removing the substrate 10 may cause pulling forces between the substrate 10 and the insulating structure 50 and further damage the semiconductor stack 120. In embodiments of the present application, removing the insulating structure 50 from the separation region ISO and forming the tapered end portion 53 of the insulating structure 50 can facilitate separation of the substrate 10 from the semiconductor stack 120, thereby reducing residual insulating material on the substrate 10 and avoiding damage to the light-emitting device 1.

In one embodiment of the present application, following the above manufacturing process, one or more transfer steps may be performed to separate the light-emitting device 1 from the supporting substrate C1 and transfer it to a target substrate (not shown). The target substrate may be, for example, a backplane of a display panel or a circuit board. The light-emitting devices 1 may be transferred and fixed to the target substrate by mass transfer. The mass transfer method includes laser transfer, electrostatic transfer, stamp transfer, and fluidic self-assembly (FSA).

In one embodiment of the present application, the substrate 10 may be a patterned substrate, that is, the top surface 10a of the substrate 10 has a patterned structure. Accordingly, the bottom surface 120b of the semiconductor stack 120 may be correspondingly patterned. In one embodiment, as shown in FIG. 2A, the top surface 10a of the substrate 10 has pyramid-like protrusions, and the bottom surface 120b of the semiconductor stack 120 has corresponding pyramid-like recesses, thereby forming a patterned structure. Light emitted by the semiconductor stack 120 may be extracted from the patterned structure at the bottom surface 120b, thereby improving the brightness of the light-emitting device 1. In one embodiment, the patterned structure includes a plurality of recesses distributed over the bottom surface 120b of the semiconductor stack 120. The recesses may be pyramid-like, hemispherical, conical, trench-like, or polygonal. In other embodiments (not shown), the patterned structure includes a plurality of protrusions distributed over the bottom surface 120b, which may be pyramid-like, hemispherical, conical, strip-like, or polygonal. The present embodiment is not limited thereto. The plurality of recesses or protrusions may be regularly or irregularly distributed. In different embodiments, the protrusions may be separate or connected, and the recesses may be separate or connected. In other embodiments, the substrate 10 may be a planar substrate. After removing the substrate 10, the bottom surface 120b of the semiconductor stack 120 may be patterned. The patterned structure may be regularly or irregularly.

Light emitted by the active region 123 may be reflected by a distributed Bragg reflector (DBR) structure and extracted from the bottom surface 120b of the semiconductor stack 120, thereby improving the brightness of the light-emitting device 1.

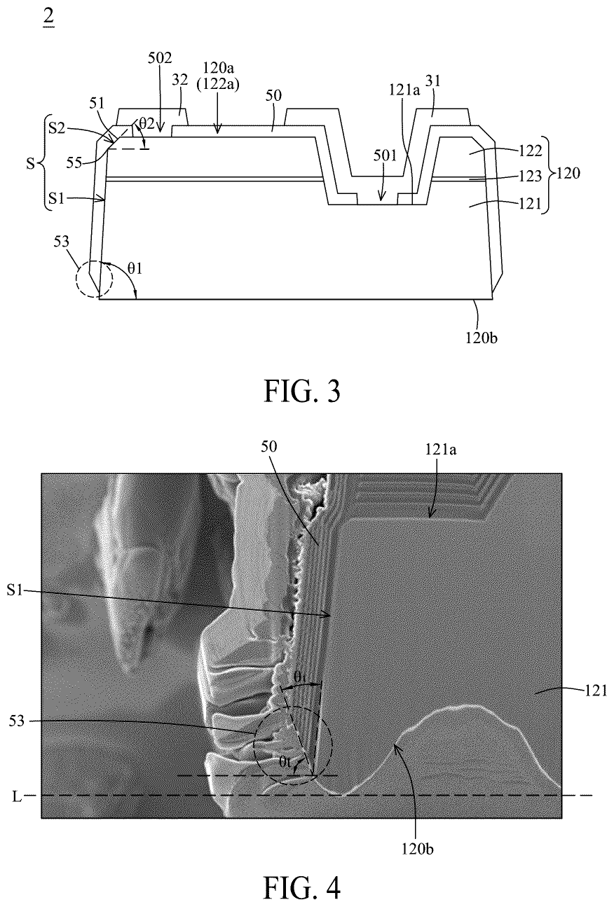

FIG. 3 shows a cross-sectional view of a light-emitting device 2 in accordance with an embodiment of the present application. As shown in FIG. 3, the light-emitting device 2 has a structure similar to that of the light-emitting device 1, and repeated features are not described in detail. The difference is that the side wall S of the light-emitting device 2 includes a first sub-side wall S1 and a second sub-side wall S2. The first sub-side wall S1 is connected to the bottom surface 120b, and the second sub-side wall S2 is connected to the top surface 120a. The first sub-side wall S1 has a first included angle θ1 relative to the bottom surface 120b, and the second sub-side wall S2 has a second included angle θ2 relative to a reference plane of the bottom surface 120b. The insulating structure 50 covers both the first sub-side wall S1 and the second sub-side wall S2. The insulating structure 50 on the first sub-side wall S1 has a gradient thickness that gradually decreases toward the bottom surface 120b. In one embodiment, the first sub-side wall S1 and the second sub-side wall S2 are directly connected.

The method for forming the semiconductor stack 120 is similar to that described above and is not repeated. The semiconductor stack 120 is then patterned by an etching process to form the first sub-side wall S1 and the second sub-side wall S2. Optionally, the first sub-side wall S1 may be etched first, followed by the second sub-side wall S2; or the second sub-side wall S2 may be etched first, followed by the first sub-side wall S1. In one embodiment, after forming the first sub-side wall S1 by etching, dry etching may be further performed from the top surface 122a of the second semiconductor layer 122 downward to remove a portion of the second semiconductor layer 122 while preserving the active region 123 and the first semiconductor layer 121, thereby forming the second sub-side wall S2 above the first sub-side wall S1. In one embodiment of the present application, the first sub-side wall S1 is etched first, followed by the second sub-side wall S2.

The first and second included angles θ1 and θ2 may be adjusted by varying etching parameters. In one embodiment, the first included angle θ1 is a right or acute angle, and the second included angle θ2 is an acute angle. In one embodiment, θ1 is between 50° and 90°, or between 60° and 90°. θ2 is between 10° and 80°, or between 45° and 75°. In one embodiment, θ2 is less than θ1.

In the present embodiment, the second sub-side wall S2 has a second included angle θ2 of not greater than 750 relative to a reference plane of the bottom surface 120b, which improves the coverage of the insulating structure 50 on the side wall S and reduces cracking of the insulating structure 50 at the corner of the side wall S, e.g., at the boundary of the top surface 120a and the side wall S.

FIG. 4 shows a scanning electron microscope (SEM) image of a light-emitting device in accordance with an embodiment of the present application. FIG. 4 shows the insulating structure 50 includes the tapered end portion 53 near the bottom surface 120b. The insulating structure 50 includes a stack of multiple sublayers.

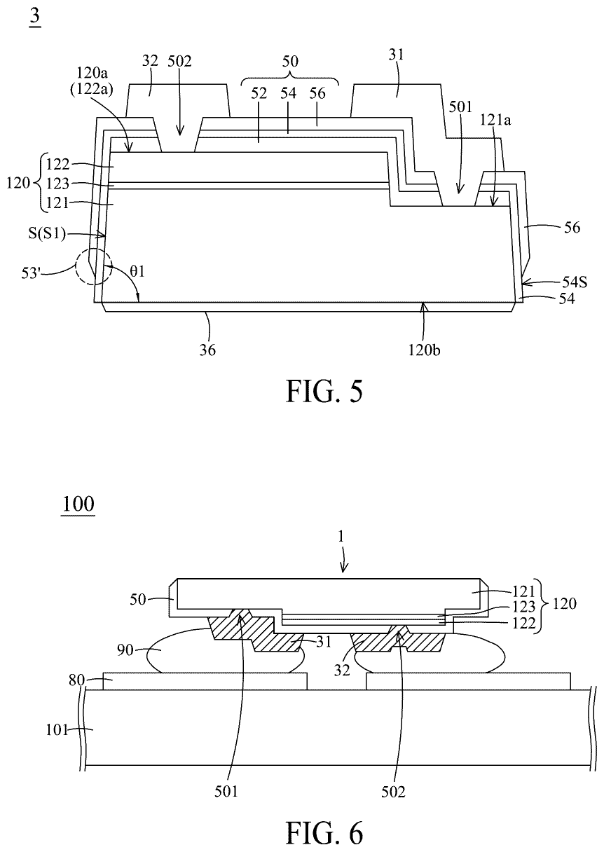

FIG. 5 shows a cross-sectional view of a light-emitting device 3 in accordance with an embodiment of the present application. As shown in FIG. 5, the light-emitting device 3 has a structure similar to that of the light-emitting device 1, and repeated features are not described. The difference is that the insulating structure 50 of the light-emitting device 3 includes a first sub-insulating structure 52, a second sub-insulating structure 54, and a third sub-insulating structure 56. The light-emitting device 3 may further include a protective layer 36 on the bottom surface 120b. The first sub-insulating structure 52 covers the top surface 121a of the first semiconductor layer 121 and the top surface 122a of the second semiconductor layer 122, but does not cover the side wall S. The second sub-insulating structure 54 and the third sub-insulating structure 56 continuously cover the side surface of the first sub-insulating structure 52 and the side wall S. The second and third sub-insulating structures 54, 56 include different materials. The thickness of the second sub-insulating structure 54 is less than that of the third sub-insulating structure 56. The second sub-insulating structure 54 may include the aforementioned dense layer to protect the side wall S and passivate defects on the side wall to reduce leakage current in the light-emitting device. In one embodiment, as shown in FIG. 5, the third sub-insulating structure 56 exposes a portion of an outer surface 54S of the second sub-insulating structure 54.

In a method of manufacturing the light-emitting device 3, after forming the second sub-insulating structure 54 and the third sub-insulating structure 56, similar to FIG. 2C, the second and third sub-insulating structures 54, 56 cover the separation region ISO. The second and third sub-insulating structures 54, 56 on the separation region ISO are then removed by, for example, etching. In one embodiment, the second sub-insulating structure 54 may be formed of a material with an etching rate lower than that of the third sub-insulating structure 56. Consequently, the second sub-insulating structure 54 is etched to a lesser extent than the third sub-insulating structure 56, thereby exposing a portion of the outer surface 54S of the second sub-insulating structure 54. In one embodiment, the second sub-insulating structure 54 completely covers the side wall S, and an end portion 53′ of the third sub-insulating structure 56 is tapered as described above.

The protective layer 36 serves to protect the bottom surface 120b, and light emitted by the semiconductor stack 120 may pass through the protective layer 36. The materials are similar to those of the insulating structure 50 and are not repeated. In different embodiments, the protective layer 36 may fully cover the bottom surface 120b or may expose a peripheral region of the bottom surface 120b (not shown). In another embodiment, the protective layer 36 may be omitted.

In one embodiment, the first sub-insulating structure 52 may include a Bragg reflector structure. In another embodiment, the first sub-insulating structure 52 may be omitted.

FIG. 6 shows a schematic cross-sectional view of a light-emitting module 100 in accordance with an embodiment of the present application. The light-emitting module 100 includes a target substrate 101. As shown in FIG. 6, any one of the light-emitting devices 1, 2 or 3 of the present application is separated from the substrate 10, transferred one or more times, and fixed to the target substrate 101. The target substrate 101 may be, for example, a driving backplane including circuits such as integrated circuits or MEMS formed thereon. Multiple electrode pads 80 are disposed on the target substrate 101 and are electrically connected to the circuits, which control the light-emitting devices. The first and second electrodes 31, 32 of the light-emitting device 1 can be electrically connected to the electrode pads 80 through eutectic bonding, solder bonding or conductive adhesive bonding via a conductive bonding layer 90. In one embodiment, the light-emitting module 100 further includes an encapsulation element covering the light-emitting device 1. The encapsulation element may include epoxy, acrylic, or silicone.

In different applications, the light-emitting module 100 may serve as a display module, a communication module, or a lighting module. The light-emitting module 100 includes a plurality of light-emitting devices (not shown) arranged on the target substrate 101. In one embodiment where the light-emitting module 100 is a display module, each light-emitting device serves as a sub-pixel, and wavelength conversion elements are disposed on the light-emitting devices so that the sub-pixels emit different colors. Adjacent sub-pixels form a pixel unit. The wavelength conversion elements may include quantum dots, phosphors, or color filters. In another embodiment, the light-emitting devices may use semiconductor stacks 120 of different materials, so that the devices emit different colors.

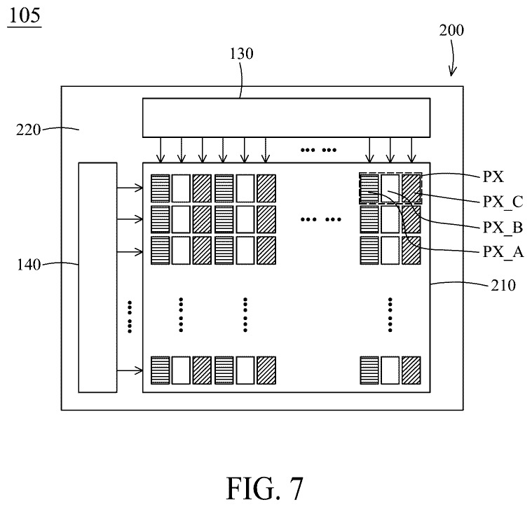

FIG. 7 shows a schematic plan view of a display module 105 in accordance with an embodiment of the present application. As shown in FIG. 7, the display module 105 includes a display substrate 200 having a display area 210 and a non-display area 220, and a plurality of pixels PX arranged in the display area 210. Each pixel PX includes a first sub-pixel PX_A, a second sub-pixel PX_B, and a third sub-pixel PX_C. A data line driver circuit 130 and a scan line driver circuit 140 are disposed in the non-display area 220. The data line driver circuit 130 is connected to the data lines of the pixels PXs (not shown) to transmit data signals to the pixels PXs, and the scan line driver circuit 140 is connected to the scan lines of the pixels PXs (not shown) to transmit scan signals to the pixels PXs. Each pixel PX includes a light-emitting device in accordance with any of the above embodiments. The sub-pixels emit different colors; in one embodiment, the first, second, and third sub-pixels PX_A, PX_B, and PX_C are red, green, and blue sub-pixels, respectively. Light-emitting devices emitting different wavelengths may be used for the respective sub-pixels to present different colors, and by combining the red, green, and blue light, the display module 105 outputs full-color images.

In one embodiment, the encapsulation element and/or the light-emitting device 1 may further include wavelength conversion elements for changing the wavelength of light generated by the light-emitting device 1. In one embodiment, the encapsulation element includes phosphor and/or scattering material. The light-emitting module 100 may be applied to a backlight unit, a display device, an indicator or a smart watch.

It will be apparent to those having ordinary skill in the art that various modifications and variations can be made to the devices in accordance with the present disclosure without departing from the scope or spirit of the disclosure. In view of the foregoing, it is intended that the present disclosure covers modifications and variations of this disclosure provided they fall within the scope of the following claims and their equivalents.

What is claimed is:

1. A semiconductor device, comprising:
a semiconductor stack, comprising a top surface, a bottom surface, and a side wall; and
an insulating structure, covering the semiconductor stack;
wherein:
the side wall comprises a first sub-side wall connected to the bottom surface; and
the insulating structure covers the first sub-side wall and a portion of the insulating structure covering the first sub-side wall comprises a gradient thickness that gradually decreases toward the bottom surface.

2. The semiconductor device of claim 1, wherein the insulating structure comprises an end portion adjacent to the bottom surface, and the end portion is tapered.

3. The semiconductor device of claim 1, wherein the first sub-side wall connects the top surface and the bottom surface.

4. The semiconductor device of claim 1, wherein a first included angle is formed between the first sub-side wall and the bottom surface the first included angle is between 50° and 90°.

5. The semiconductor device of claim 1, wherein the side wall further comprises a second sub-side wall connected to the top surface and the first sub-side wall.

6. The semiconductor device of claim 5, wherein the second sub-side wall forms a second included angle with a reference plane parallel to the bottom surface, and the second included angle is an acute angle.

7. The semiconductor device of claim 6, wherein a first included angle is formed between the first sub-side wall and the bottom surface;
the first included angle is a right angle or an acute angle; and
the second included angle is less than the first included angle.

8. The semiconductor device of claim 7, wherein the first included angle is between 50° and 90°, and the second included angle is between 10° and 80°.

9. The semiconductor device of claim 1, wherein the bottom surface comprises a patterned structure.

10. The semiconductor device of claim 1, wherein the insulating structure comprises a plurality of first sublayers and a plurality of second sublayers alternately stacked; and
wherein the first sublayer and the second sublayer comprise different refractive indexes.

11. The semiconductor device of claim 10, wherein the insulating structure comprises a distributed Bragg reflector structure.

12. The semiconductor device of claim 1, wherein in a plan view of the semiconductor device, a diagonal length of the semiconductor device is between 1 and 200 μm.

13. The semiconductor device of claim 1, wherein the insulating structure comprises a first sub-insulating structure and a second sub-insulating structure;
wherein the first sub-insulating structure is between the side wall and the second sub-insulating structure;
wherein the second sub-insulating structure comprises the gradient thickness.

14. The semiconductor device of claim 13, wherein the first sub-insulating structure comprises a portion uncovered by the second sub-insulating structure.

15. The semiconductor device of claim 1, wherein the insulating structure comprises a first sub-insulating structure and a second sub-insulating structure;
wherein the first sub-insulating structure is between the semiconductor stack and the second sub-insulating structure;
wherein the second sub-insulating structure comprises the gradient thickness.

16. The semiconductor device of claim 15, wherein the side wall is uncovered by the first sub-insulating structure.

17. The semiconductor device of claim 16, wherein the first sub-insulating structure comprises a distributed Bragg reflector structure.

18. The semiconductor device of claim 1, wherein the first sub-side wall comprises a portion near the bottom surface which is uncovered by the insulating structure.

19. The semiconductor device of claim 1, further comprising a protective layer covering the bottom surface.

20. A light-emitting module, comprising:
a target substrate;
a conductive bonding layer; and
the semiconductor device according to claim 1
connected to the target substrate by the conductive bonding layer.
